(19) United States
(12) Patent Application Publication
(10) Pub. No.: US 2014/0138738 A1
(43) Pub. Date: May 22, 2014

(54) SEMICONDUCTOR DEVICE

(71) Applicant: Tomohiko SATO, Toyota-shi (JP)

(72) Inventor: Tomohiko SATO, Toyota-shi (JP)

(73) Assignee: TOYOTA JIDOSHA KABUSHIKI KAISHA, Toyota-shi (JP)

(21) Appl. No.: 14/065,743

(22) Filed: Oct. 29, 2013

(30) Foreign Application Priority Data
Nov. 22, 2012 (JP) 2012-256135

(51) Int. Cl. H01L 29/06; H01L 29/10; H01L 27/06; H01L 29/739; H01L 29/423

(52) U.S. Cl. CPC H01L 29/0607; H01L 29/7397; H01L 29/4236; H01L 27/0664; H01L 29/1095
USPC 257/140

(57) ABSTRACT

A semiconductor device includes: a channel region, having: a first trench gate, in which a bottom end in a depth direction protrudes into a first drift region, and a non-channel region, having: a second trench gate, in which a bottom end in the depth direction protrudes into a second drift region, that is adjacent to the first trench gate, and protruding length of the second trench gate is shorter than the protruding length of the first trench gate that protrudes into the first drift region.

### INCORPORATION BY REFERENCE

The disclosure of Japanese Patent Application No. 2012-256135 filed on Nov. 22, 2012 including the specification, drawings and abstract is incorporated herein by reference in its entirety.

### BACKGROUND OF THE INVENTION

1. Field of the Invention

The present invention relates to a semiconductor device.

2. Description of Related Art

Japanese Patent Application Publication No. 2002-190595 (JP 2002-190595 A) discloses an insulated gate bipolar transistor (IGBT) that has a trench gate structure and in which a bottom end of a part of a body region in a depth direction is positioned deeper than the bottom end of a trench in the depth direction. The IGBT disclosed in JP 2002-190595 A is intended to suppress the concentration of an electric field on the bottom end of the trench and to improve withstand voltage when the IGBT is turned off.

In general, gate-collector capacitance Cgc in the IGBT having the trench gate structure is proportional to the length of the trench in the depth direction that protrudes into a drift region (that is, surface area). Furthermore, surge voltage at turning-off of the IGBT is proportional to the magnitude of the gate-collector capacitance Cgc in the IGBT. Thus, as the length of the trench in the depth direction that protrudes into a drift region gets longer, the surge voltage at the turning-off increases.

In the IGBT disclosed in JP 2002-190595 A, the bottom ends of a plurality of trenches uniformly protrude into the drift region by the same length regardless of the position. Thus, in order to reduce the gate-collector capacitance Cgc in the IGBT, the length in which the trench protrudes into the drift region has to be shortened. However, the positions of the bottom ends of the trenches may vary due to errors in production or other factors, and thus if the length in which each trench protrudes into the drift region is determined to be short, a gate threshold that is a threshold of gate voltage required for turning on the IGBT may vary. In order to suppress variations in the gate threshold, the bottom end of the trench is determined to protrude into the drift region by at least a specified length. As a result, the value of the gate-collector capacitance Cgc cannot be reduced, and the surge voltage at the turning-off cannot be decreased in some cases.

### SUMMARY OF THE INVENTION

The present invention provides a semiconductor device capable of appropriately suppressing the variations in the gate threshold and the surge voltage at the turning-off.

A semiconductor device according to a first aspect of the present invention includes: a channel region, having: a contact region of a first conductive type; a first body region of a second conductive type that is disposed at a deeper position than the contact region and adjacent to the contact region; a first drift region of the first conductive type that is disposed at a deeper position than the first body region and separated from the contact region with the first body region; and a first trench gate that penetrates through the contact region and the first body region, in which a bottom end in a depth direction protrudes into the first drift region, a first insulating film comes in contact with an inner surface of the first trench gate, and a first gate electrode comes in contact with the first insulating film, and a non-channel region, having: a second body region of the second conductive type in which the contact region is disposed at the same depth position as an opposite surface of a surface adjacent to the first body region; a second drift region of the first conductive type that is disposed at a deeper position than the second body region and adjacent to the second body region; and a second trench gate that penetrates through the second body region, in which a bottom end in the depth direction protrudes into the second drift region, that is adjacent to the first trench gate, in which a second insulating film in contact with an inner surface of the second trench gate comes in contact with the first insulating film, a second gate electrode in contact with the second insulating film comes in contact with the first gate electrode, and protruding length of the second trench gate is shorter than the protruding length of the first trench gate that protrudes into the first drift region.

A semiconductor device according to a second aspect of the present invention includes: a semiconductor substrate that is provided with a trench, an insulating film which encloses an inner surfaces of the trench, and a gate electrode which is housed in the trench in an enclosed state by the insulating film; in which a channel region and a non-channel region are disposed along a longitudinal direction of the trench when the semiconductor substrate is viewed in a plan view; the trench includes a first trench part that is positioned within the channel region and a second trench part that is positioned within the non-channel region; a front-side electrode is connected on a front side of the semiconductor substrate; a back-side electrode is connected on a back side of the semiconductor substrate; when the semiconductor substrate is viewed from a first section that is cut along a plane orthogonal to the longitudinal direction of the trench in the channel region, the channel region includes: a contact region of a first conductive type that is provided on a front side of the semiconductor substrate; a first body region of a second conductive type that is disposed at a deeper position than the contact region and adjacent to the contact region; and a first drift region of the first conductive type that is disposed at a deeper position than the first body region and separated from the contact region with the first body region; the first trench part is formed from the front side of the semiconductor substrate through the contact region and the first body region, in which a bottom end in a depth direction protrudes into the first drift region; when the semiconductor substrate is viewed from a second section that is cut along a plane orthogonal to the longitudinal direction of the trench in the non-channel region, the non-channel region includes: a second body region of a second conductive type that is provided on a front side of the semiconductor substrate; and a second drift region of the first conductive type that is disposed at a deeper position than the second body region and adjacent to the second body region; the second trench part is formed from the front side of the semiconductor substrate through the second body region, in which a bottom end in a depth direction protrudes into the second drift region; and a protruding length of the second trench part protruding into the second drift region is shorter than that of the first trench part protruding into the first drift region.

The aforementioned terms “the bottom end of the trench part protrudes into the drift region” includes a case where the bottom end of the trench part comes in contact with the drift region. Thus, a case where the position of the bottom end of the trench part is the same as the position of the bottom end of the body region and the bottom end of the trench part comes in contact with the drift region also corresponds to the terms “the bottom end of the trench part protrudes into the drift region”. It should be noted that the protruding length of the trench part in this case becomes “0”.

According to the aspects described above, variations in the gate threshold can be suppressed appropriately, and surge voltage at turning-off can be suppressed appropriately as well.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a plan view that shows a semiconductor device according to a first embodiment of the present invention;

FIG. 2 is a cross-sectional view taken along the line II-II in FIG. 1;

FIG. 3 is a cross-sectional view taken along the line III-III in FIG. 1;

FIG. 4 is a cross-sectional view taken along the line IV-IV in FIG. 1;

FIG. 5 is a cross-sectional view that shows a semiconductor device according to a second embodiment of the present invention (corresponding to the III-III section in FIG. 1);

FIG. 6 is a cross-sectional view that shows a semiconductor device according to a third embodiment of the present invention (corresponding to the III-III section in FIG. 1);

FIG. 7 is a cross-sectional view that shows a semiconductor device according to a fourth embodiment of the present invention (corresponding to the III-III section in FIG. 1);

FIG. 8 is a plan view that shows a semiconductor device according to a fifth embodiment of the present invention;

FIG. 9 is a cross-sectional view taken along the line IX-IX in FIG. 8; and

FIG. 10 is a cross-sectional view taken along the line X-X in FIG. 8.

### DETAILED DESCRIPTION OF EMBODIMENTS

### First Embodiment

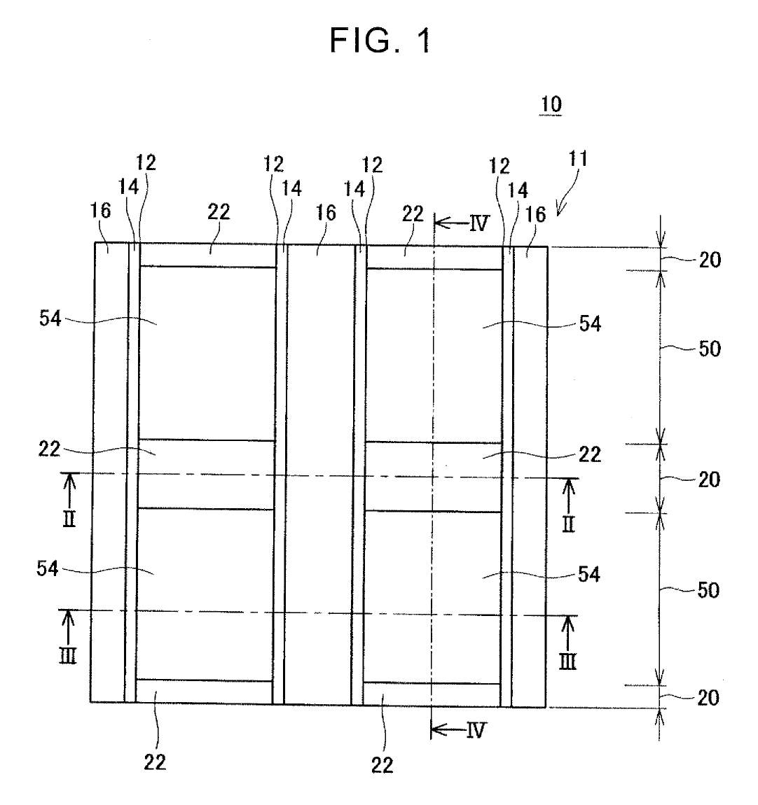

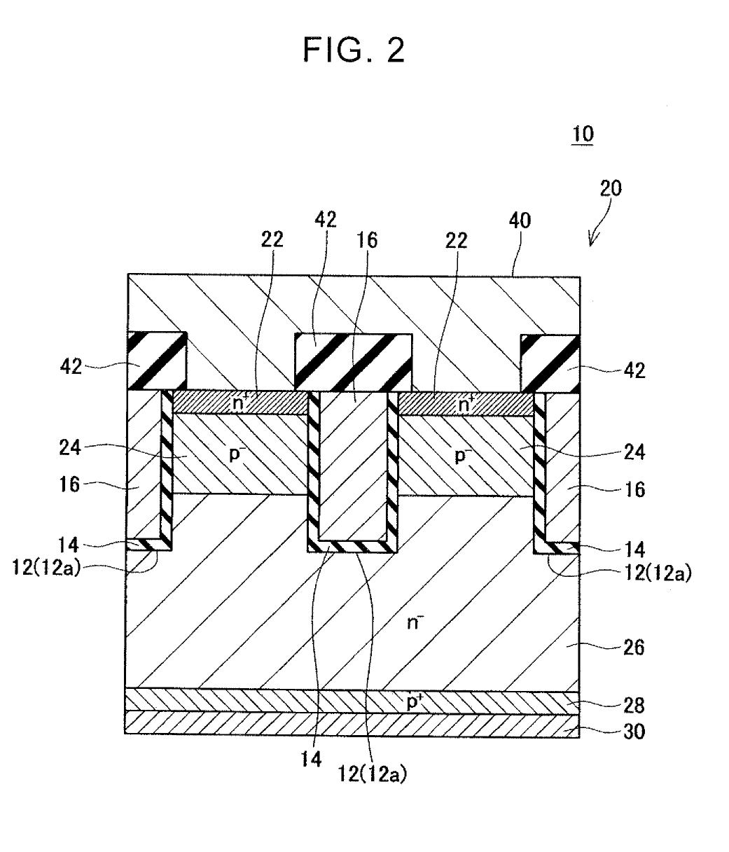

A semiconductor device 10 according to this embodiment shown in FIG. 1 includes a semiconductor substrate 11 that is mainly made of silicon (Si), various electrodes, insulating films, metal lines, and other components. The semiconductor device 10 according to this embodiment is an IGBT. In FIG. 1, the graphical representation of an insulating layer 42 and an emitter electrode 40 (see FIG. 2) that are provided on a front side of the semiconductor substrate 11 is omitted.

As shown in FIG. 1, the semiconductor substrate 11 includes a plurality of trenches 12, gate insulating films 14, and gate electrodes 16. The trenches 12 extend in upward and downward direction of FIG. 1 and are formed in right and left direction of FIG. 1 at equal intervals. A gate insulating film 14 covers the inner side of a trench 12. A gate electrode 16 is housed in the trench 12 in a state of being covered with the gate insulating film 14.

As shown in FIG. 1, when the semiconductor substrate 11 is viewed in a plan view, the semiconductor substrate 11 includes channel regions 20 and non-channel regions 50 that are alternately disposed along the longitudinal direction of the trench 12 (upward and downward direction of FIG. 1).

With reference to FIG. 2, a channel region 20 is described. FIG. 2 is a cross-sectional view that is taken along the line II-II in FIG. 1 and shows the section of the semiconductor substrate 11 that is cut along a plane orthogonal to the longitudinal direction of the trench 12 in the channel region 20. As shown in FIG. 2, the channel region 20 is formed with an emitter region 22, a first body region 24, a first drift region 26, a first collector region 28, and a plurality of gate electrodes 16. The emitter electrode 40 is formed over the entire front side (upper surface in FIG. 2) of the semiconductor substrate 11. A collector electrode 30 is formed over the entire back side (lower surface in FIG. 2) of the semiconductor substrate 11.

The emitter region 22 is formed in an area that is exposed to the front side of the semiconductor substrate 11. The emitter region 22 is also formed in an area that comes into contact with the gate insulating film 14 in a first trench part 12a. The emitter region 22 is n-type, and the impurity concentration thereof is higher than that of the first drift region 26. The front side of the emitter region 22 is ohmically connected to the emitter electrode 40.

The first body region 24 is disposed at a deeper position than the emitter region 22 and adjacent to the emitter region 22. The first body region 24 is formed in a shallower range than a bottom end of the first trench part 12a. The first body region 24 is p-type.

The first drift region 26 is disposed at a deeper position than the first body region 24. The first drift region 26 is separated from the emitter region 22 with the first body region 24. The first drift region 26 is n-type, and the impurity concentration thereof is lower than that of the emitter region 22.

The first collector region 28 is disposed at a deeper position than the first drift region 26. The first collector region 28 is separated from the first body region 24 with the first drift region 26. The first collector region 28 is formed in an area that is exposed to the back side of the semiconductor substrate 11. The first collector region 28 is p-type, and the impurity concentration thereof is higher than that of the first body region 24. The back side of the first collector region 28 is ohmically connected to the collector electrode 30.

The channel region 20 is formed with the first trench part 12a among the trenches 12 (see FIG. 1) which is a part positioning in the channel region 20. The first trench part 12a is formed from the front side of the semiconductor substrate 11 through the emitter region 22 and the first body region 24. The bottom end of the first trench part 12a in depth direction protrudes from the bottom end of the first body region 24 to the inside of the first drift region 26 by a specified length. As described above, the gate electrode 16 that is enclosed with the gate insulating film 14 is provided inside the first trench part 12a. The gate electrode 16 is covered with the insulating layer 42 on the upper surface and insulated from the emitter electrode 40. However, the gate electrode 16 is allowed to make contact with the outside at the position that is not shown in drawings.

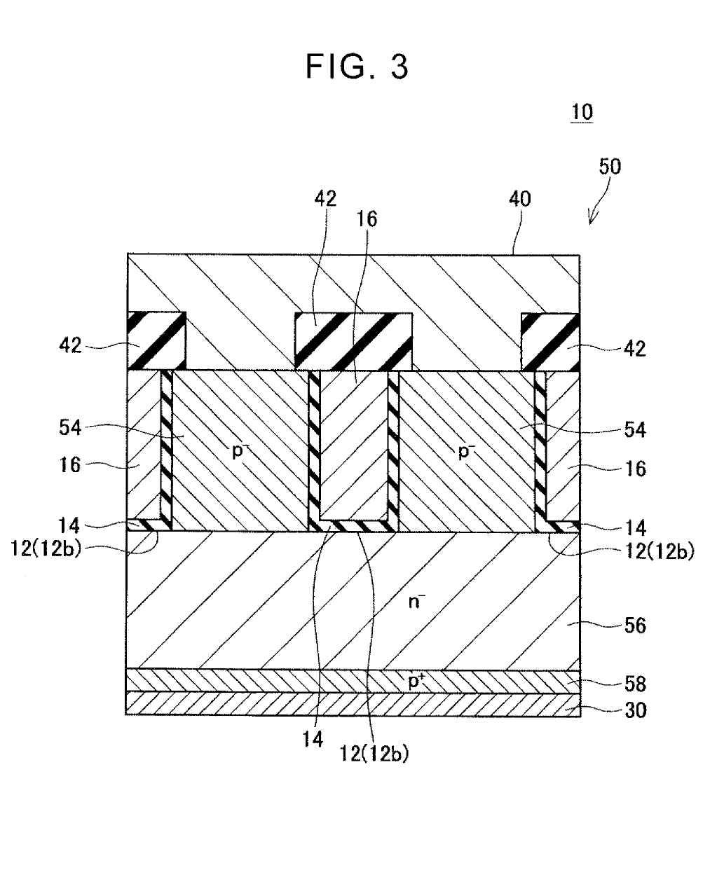

Next, the non-channel region 50 will be described with reference to FIG. 3. FIG. 3 is a cross-sectional view that is taken along the line III-III in FIG. 1 and shows the section of the semiconductor substrate 11 that is cut along a plane orthogonal to the longitudinal direction of the trench 12 in the non-channel region 50. As shown in FIG. 3, the non-channel region 50 is formed with a second body region 54, a second drift region 56, a second collector region 58, and a plurality of gate electrodes 16. It should be noted that the non-channel region 50 is formed with no emitter region 22 on the front side of the semiconductor substrate 11.

The second body region 54 is formed in an area that is exposed to the front side of the semiconductor substrate 11. The second body region 54 is formed such that the bottom end thereof in the depth direction is positioned lower than the bottom end of the first body region 24 in the channel region 20 (see FIG. 1). The second body region 54 is p-type. The front side of the second body region 54 is ohmically connected to the emitter electrode 40. It should be noted that in other examples, a p+-type contact region that has a higher impurity concentration than other parts in the second body region 54 may be provided in an area that is exposed to the front side of the semiconductor substrate 11 in the second body region 54.

The second drift region 56 is disposed at a deeper position than the second body region 54 and adjacent to the second body region 54. The second drift region 56 is n-type, and the impurity concentration thereof is lower than that of the emitter region 22.

The second collector region 58 is disposed at a deeper position than the second drift region 56. The second collector region 58 is separated from the second body region 54 with the second drift region 56. The second collector region 58 is formed in an area that is exposed to the back side of the semiconductor substrate 11. The second collector region 58 is p-type, and the impurity concentration thereof is higher than that of the second body region 54. The back side of the second collector region 58 is ohmically connected to the collector electrode 30.

The non-channel region 50 is formed with the second trench part 12b among the trenches 12 (see FIG. 1) which is a part positioning in the non-channel region 50. The second trench part 12b is formed from the front side of the semiconductor substrate 11 through the second body region 54. The bottom end of the second trench part 12b in depth direction comes into contact with the second drift region 56 without being buried in the second body region 54. More specifically, the bottom end of the second trench part 12b faces the front side of the second drift region 56. This case is also one example of “the bottom end of the trench part protrudes into the drift region.” It should be noted that the protruding length of the second trench part 12b in this case becomes “0”. As described above, the gate electrode 16 that is enclosed with the gate insulating film 14 is provided inside the second trench part 12b. The gate electrode 16 is covered with the insulating layer 42 on the upper surface and insulated from the emitter electrode 40.

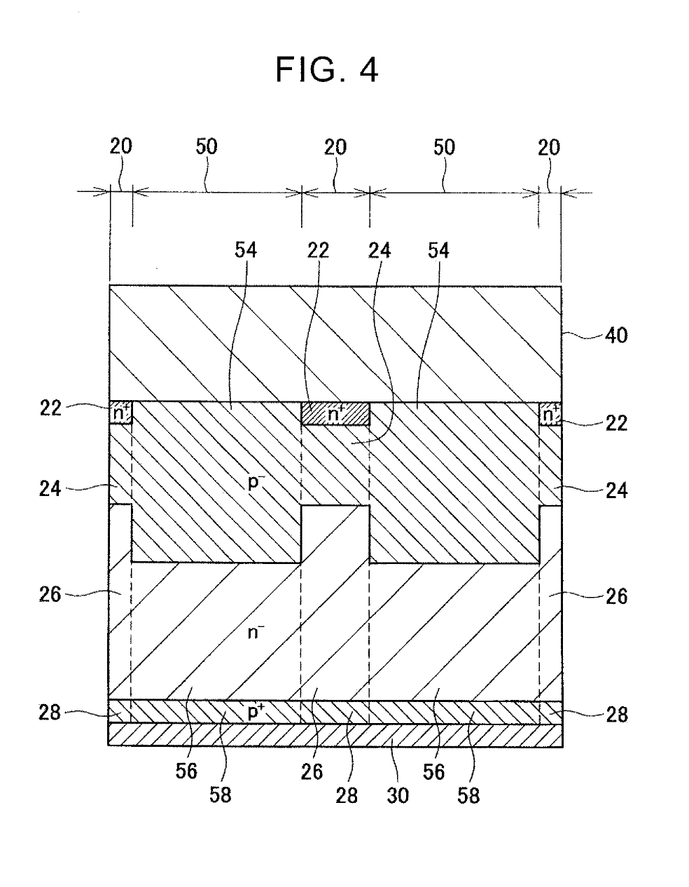

The channel region 20 and the non-channel region 50 will be described further with reference to FIG. 4. FIG. 4 is a cross-sectional view that is taken along the line IV-IV in FIG. 1 and shows the section of the semiconductor substrate 11 that is cut along a plane in parallel with the longitudinal direction of the trench 12. As shown in FIG. 4, the first body region 24 and the second body region 54 have approximately the same impurity concentration and are formed contiguously. The bottom end of the second body region 54 in the depth direction is formed at a deeper position than the bottom end of the first body region 24 in the depth direction. The first drift region 26 and the second drift region 56 also have approximately the same impurity concentration and are formed contiguously. The first collector region 28 and the second collector region 58 are also similar to the components described above.

As shown in FIGS. 2 and 3, in this embodiment, the trench 12 is formed in a uniform depth at any part. In other words, the first trench part 12a and the second trench part 12b are formed in the same depth. However, as described above, the bottom end of the second body region 54 is formed at a deeper position than the bottom end of the first body region 24 in this embodiment. Consequently, the protruding length in which the bottom end of the second trench part 12b protrudes into the second drift region 56 is shorter than the protruding length in which the bottom end of the first trench part 12a protrudes into the first drift region 26.

Operation of the semiconductor device (IGBT) 10 according to this embodiment will be described next. The voltage in which the collector electrode 30 becomes positively charged (forward voltage) is applied between the emitter electrode 40 and the collector electrode 30. An ON-potential (potential greater than a required potential for the formation of a channel) is applied to the gate electrode 16. This causes the semiconductor device 10 to be turned on. In other words, for the channel region 20 where the emitter region 22 is formed (see FIG. 2), a channel is formed within the first body region 24 in a range in contact with the gate insulating film 14 due to the application of the ON-potential to the gate electrode 16. Subsequently, an electron flows from the emitter electrode 40 to the collector electrode 30 through the emitter region 22, the channel, the first and the second drift regions 26 and 56, and the first and the second collector regions 28 and 58. Additionally, a hole flows from the collector electrode 30 to the emitter electrode 40 through the first and the second collector regions 28 and 58, the first and the second drift regions 26 and 56, and the first and the second body regions 24 and 54. In other words, an electric current flows from the collector electrode 30 to the emitter electrode 40. On the other hand, for the non-channel region 50 that includes no emitter region 22 (see FIG. 3), a channel is not formed within the second body region 54 in a range in contact with the gate insulating film 14 when the ON-potential is applied to the gate electrode 16.

The channel that is formed within the channel region 20 vanishes when the potential applied to the gate electrode 16 is changed from the ON-potential to OFF-potential. However, a carrier that remains in the first drift region 26 keeps the electric current (referred to as a tail current) flowing through the semiconductor device 10 for a short time. The tail current attenuates within a short time, and then the electric current flowing through the semiconductor device 10 becomes approximately zero. That is to say, the semiconductor device 10 is turned off. While the semiconductor device 10 is turned off, a depletion layer is formed between the first body region 24 and the second body region 54 and between the first drift region 26 and the second drift region 56.

The structure and operation of the semiconductor device 10 according to this embodiment has been described so far. As described above, the non-channel region 50 of the semiconductor device 10 according to this embodiment (see FIG. 3) is formed with no emitter region 22 on the front side of the semiconductor substrate 11, and thus the channel is not formed even when voltage is applied to the gate electrode 16 in the second trench part 12b. Consequently, even if the protruding length of the second trench part 12b protruding into the second drift region 56 is made shorter than that of the first trench part 12a protruding into the first drift region 26, a gate threshold in the entire semiconductor device 10 is not affected. In other words, variations in the gate threshold in the entire semiconductor device 10 can be suppressed appropriately. Additionally, the protruding length of the second trench part 12b protruding into the second drift region 56 is shorter than that of the first trench part 12a protruding into the first drift region 26 in the semiconductor device 10. In other words, the value of gate-collector capacitance Cgc can be reduced in the non-channel region 50 in comparison with the channel region 20. Thus, the value of gate-collector capacitance Cgc in the entire semiconductor device 10 can be reduced in comparison with the semiconductor device having a conventional structure such that the bottom ends of the trenches uniformly protrude into the drift region by the same length regardless of the position on the semiconductor device. Consequently, surge voltage at turning-off can be suppressed appropriately. Therefore, the semiconductor device 10 according to this embodiment can appropriately suppress the variations in the gate threshold and the surge voltage at turning-off as well.

In this embodiment, the bottom end of the second body region 54 is formed at a deeper position than the bottom end of the first body region 24, and the bottom end of the second trench part 12b faces the front side of the second drift region 56. Thus, while the semiconductor device 10 is turned off, the shape of the depletion layer extending from the second body region 54 can be smoothed, and the electric field concentration on the bottom end of the second trench part 12b can be relaxed. Consequently, the withstand voltage of the entire semiconductor device 10 can be prevented from decreasing.

In this embodiment, the bottom end of the second trench part 12b in the non-channel region 50 (see FIG. 3) protrudes into the second drift region 56 (faces the front side of the second drift region 56) without being buried in the second body region 54. Thus, while the semiconductor device 10 is turned on, the carrier (hole) in the second drift region 56 flows into the second body region 54, and this prevents the carrier in the second drift region 56 from decreasing. Consequently, ON-state voltage of the semiconductor device 10 can be prevented from increasing.

The correlation between this embodiment and attached claims will be described next. The emitter region 22 is one example of the “contact region”. The emitter electrode 40 and the collector electrode 30 are examples of the “front side electrode” and the “back side electrode”, respectively. The cross sections shown in FIGS. 2 and 3 are examples of the “first cross section” and the “second cross section”, respectively.

### Second Embodiment

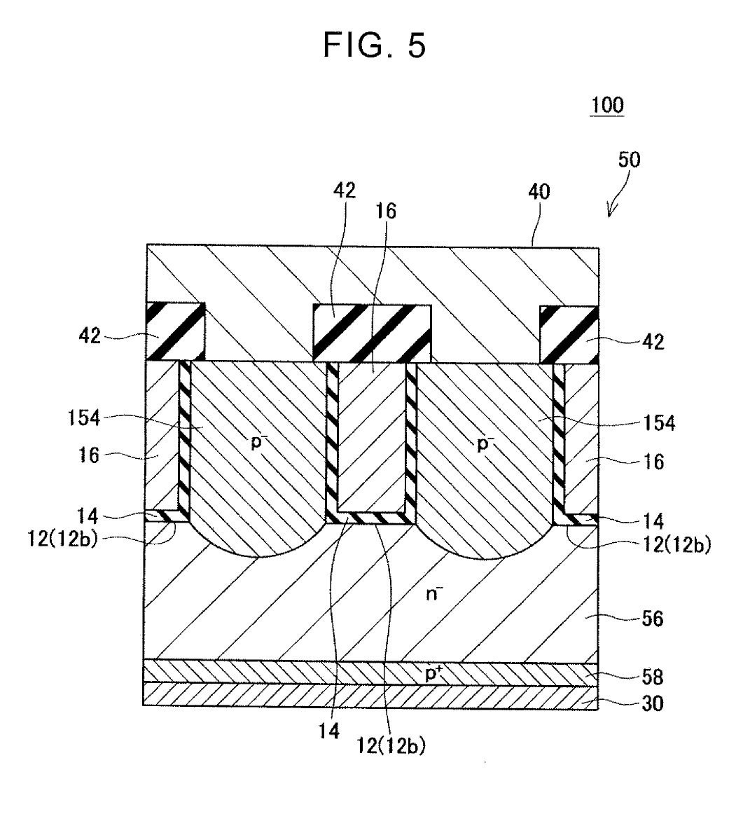

Next, the semiconductor device 100 according to the second embodiment will be described with reference to FIG. 5 with emphasis on different points from the first embodiment. The semiconductor device 100 according to this embodiment is an IGBT similar to the semiconductor device 10 according to the first embodiment. The basic structure of the channel region 20 of the semiconductor device 100 is the same as that of the semiconductor device 10 according to the first embodiment. FIG. 5 is a cross-sectional view that shows the section of the semiconductor device 100 according to this embodiment which corresponds to the III-III section in FIG. 1. As shown in FIG. 5, the semiconductor device 100 according to this embodiment is different from the semiconductor device 10 according to the first embodiment in the shape of the second body region 154 within the non-channel region 50. The bottom end of the second body region 154 according to this embodiment is shaped into a curve that protrudes in the depth direction. More specifically, the bottom end of the second body region 154 is formed with the shallowest level at end portions in width direction in contact with the second trench part 12b and the deepest level in the middle portion. The deepest part in the bottom end of the second body region 154 is formed at a deeper position than the bottom end of the second trench part 12b.

However, in this embodiment, the bottom end of the second trench part 12b protrudes into the second drift region 56 (to be exact, faces the front side of the second drift region 56) without being buried in the second body region 154.

The semiconductor device 100 according to this embodiment can provide the same operation and effects as the semiconductor device 10 according to the first embodiment described above. Furthermore, in this embodiment, the bottom end of the second body region 154 is shaped into a curve that protrudes in the depth direction. Thus, while the semiconductor device 100 is turned off, the shape of the depletion layer extending from the second body region 154 toward the second drift region 56 can be smoothed, and the electric field concentration on the bottom end of the second trench part 12b can be relaxed. Consequently, the withstand voltage of the entire semiconductor device 100 can be prevented from decreasing more effectively.

### Third Embodiment

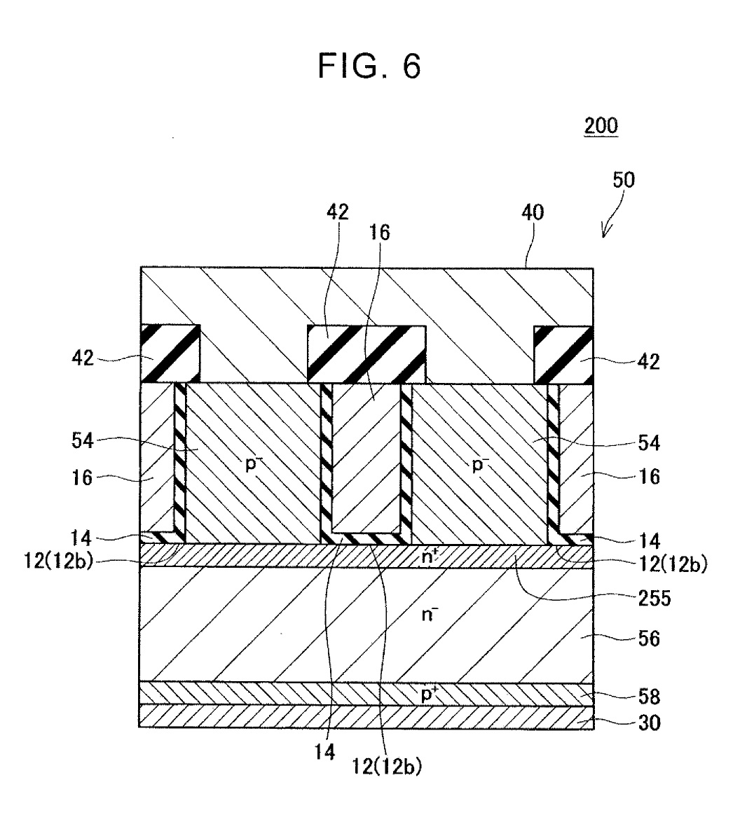

Next, a semiconductor device 200 according to the third embodiment will be described with reference to FIG. 6 with emphasis on different points from the first embodiment. The semiconductor device 200 according to this embodiment is an IGBT similar to the semiconductor device 10 according to the first embodiment. The basic structure of the channel region 20 of the semiconductor device 200 is the same as that of the semiconductor device 10 according to the first embodiment. FIG. 6 is a cross-sectional view that shows the section of the semiconductor device 200 according to this embodiment which corresponds to the III-III section in FIG. 1. As shown in FIG. 6, the semiconductor device 200 according to this embodiment is different from the first embodiment in terms that an n-type carrier storage region 255 is foamed between the second body region 54 and the second drift region 56 in the non-channel region 50. The impurity concentration of the carrier storage region 255 is higher than that of the second drift region 56.

Because this embodiment has the carrier storage region 255 as described above between the second body region 54 and the second drift region 56, the flow of the carrier (hole) from the second drift region 56 into the second body region 54 can be suppressed when the semiconductor device 200 is turned on. Thus, the second drift region 56 gets the large amount of the carriers, and the electric resistance of the second drift region 56 decreases. Consequently, the ON-state voltage of the semiconductor device 200 decreases.

### Fourth Embodiment

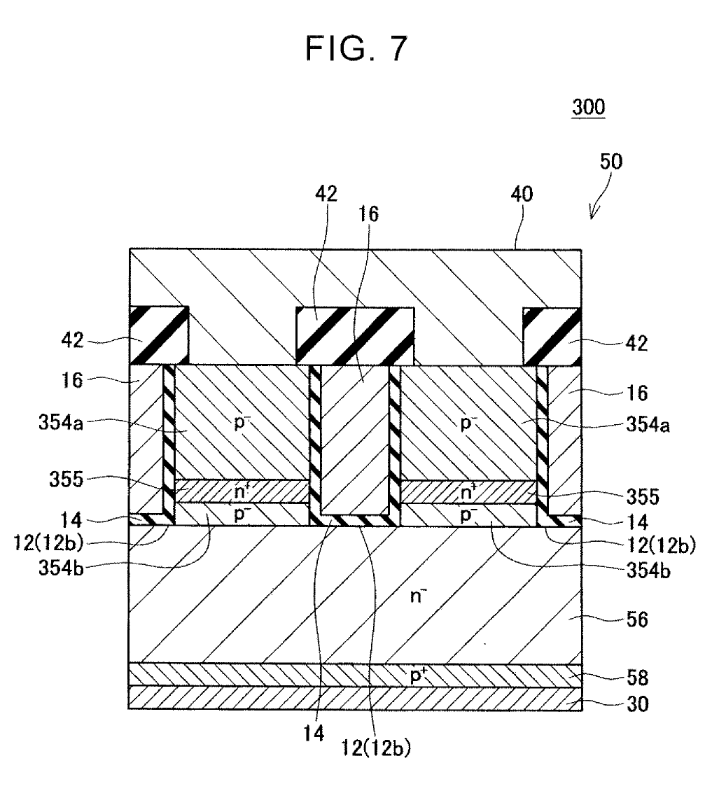

Next, a semiconductor device 300 according to the fourth embodiment will be described with reference to FIG. 7 with emphasis on different points from the first embodiment. The semiconductor device 300 according to this embodiment is an IGBT similar to the semiconductor device 10 according to the first embodiment. The basic structure of the channel region 20 of the semiconductor device 300 is the same as that of the semiconductor device 10 according to the first embodiment. FIG. 7 is a cross-sectional view that shows the section of the semiconductor device 300 according to this embodiment which corresponds to the section in FIG. 1. As shown in FIG. 7, the semiconductor device 300 according to this embodiment is different from the semiconductor device 10 according to the first embodiment in terms that a floating region 355 is provided in the second body region within the non-channel region 50. In this embodiment, the second body region of the non-channel region 50 includes a top body region 354a that is provided at a shallow level and a bottom body region 354b that is provided at a deeper level than the top body region 354a. In this embodiment, the floating region 355 is formed between the top body region 354a and the bottom body region 354b.

Both of the top body region 354a and the bottom body region 354b are p-type. In this embodiment, the bottom body region 354b is formed such that the bottom end thereof in the depth direction is positioned lower than the bottom end of the first body region 24 in the channel region 20 (see FIG. 2). The floating region 355 is n-type, and the impurity concentration thereof is higher than that of the second drift region 56.

In this embodiment, the floating region 355 as described above is included in the second body region (that is, between the top body region 354a and the bottom body region 354b). In this case, the flow of the carrier (hole) from the second drift region 56 into the second body region 54 (the top body region 354a and the bottom body region 354b) can be suppressed when the semiconductor device 300 is turned on. Thus, the second drift region 56 gets the large amount of the carriers, and the electric resistance of the second drift region 56 decreases. Consequently, the ON-state voltage of the semiconductor device 300 decreases.

### Fifth Embodiment

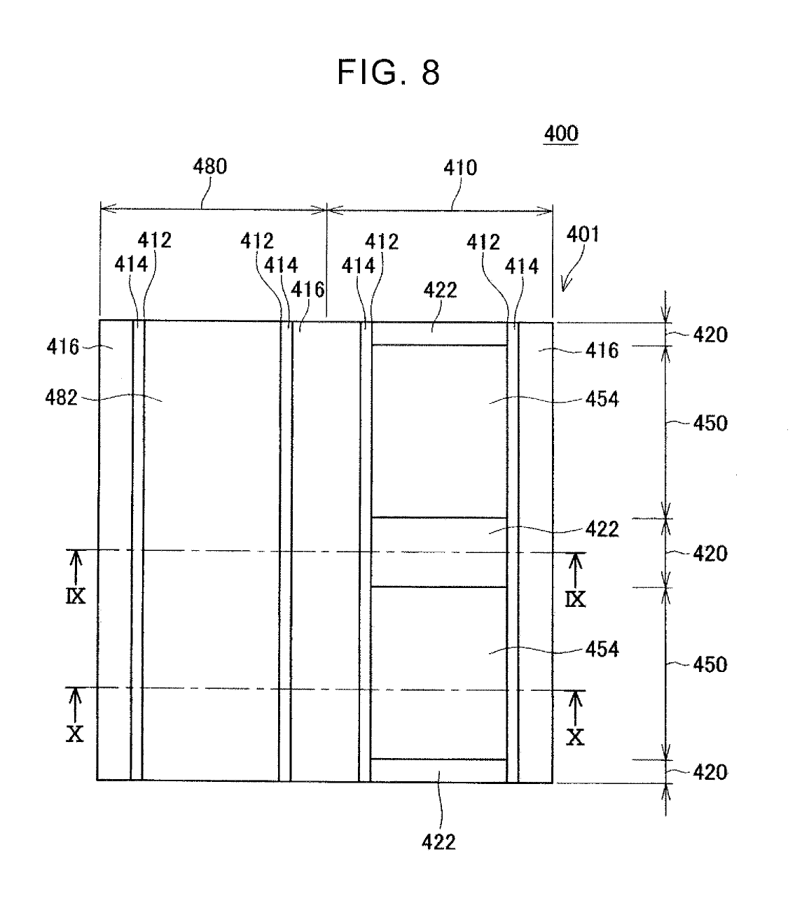

Next, a semiconductor device 400 according to the fifth embodiment will be described with reference to FIGS. 8 through 10 with emphasis on different points from the first embodiment. The semiconductor device 400 according to this embodiment is different from the first embodiment in terms of an RC-IGBT in which a semiconductor substrate 401 is formed with a diode region 480 and an IGBT region 410. In FIG. 8, the graphical representation of an insulating layer 442 and a front-side electrode 440 that are provided on the front side of the semiconductor substrate 401 is omitted.

As shown in FIG. 8, the semiconductor substrate 401 in this embodiment includes a plurality of trenches 412, gate insulating films 414, and gate electrodes 416. In the direction that is orthogonal to the longitudinal direction of the trench 412 (right and left direction in FIG. 8), the IGBT region 410 is formed in a half (right half in FIG. 8) of the semiconductor substrate 401, and the diode region 480 is formed in the other half (left half in FIG. 8) of the semiconductor substrate 401. The IGBT region 410 includes channel regions 420 and non-channel regions 450 that are alternately disposed along the longitudinal direction of the trench 412 (upward and downward direction in FIG. 8).

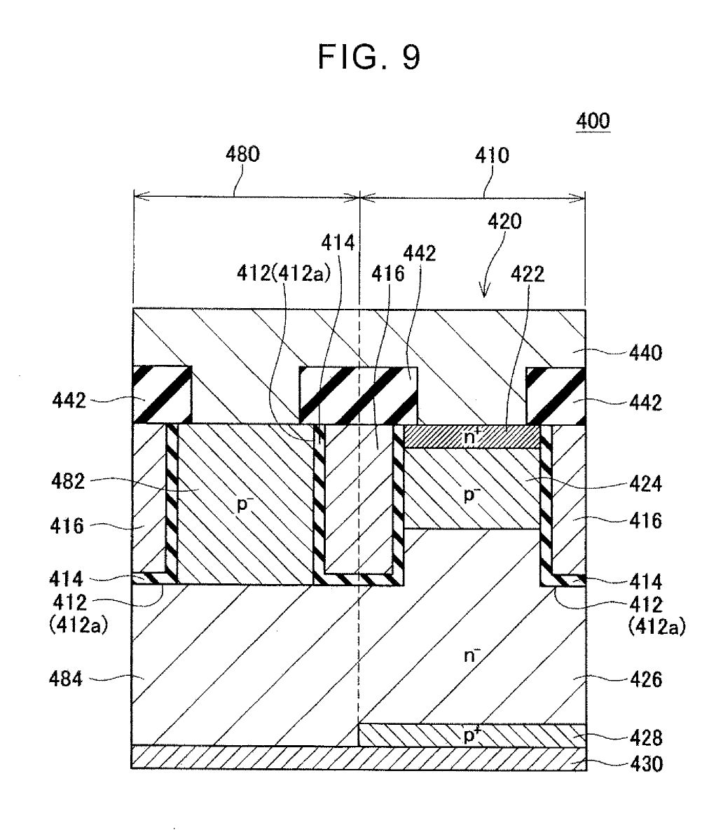

The channel region 420 in the IGBT region 410 and the diode region 480 will be described with reference to FIG. 9. In this- embodiment, the front-side electrode 440 is formed over the entire front side (upper surface in FIG. 9) of the semiconductor substrate 401. A back-side electrode 430 is formed over the entire back side (lower surface in FIG. 9) of the semiconductor substrate 401.

As shown in FIG. 9, the channel region 420 of the IGBT region 410 is formed with an emitter region 422, a first body region 424, a first drift region 426, a first collector region 428, and a plurality of gate electrodes 416. These regions 422 through 428 and a gate electrode 416 described above are the same as the regions 22 through 28 and the gate electrode 16 in the channel region 20 of the semiconductor device (IGBT) 10 according to the first embodiment. In this embodiment, the channel region 420 of the IGBT region 410 is formed with a first trench part 412a among the trenches 412 (see FIG. 8) which is a part positioning in the channel region 420. The first trench part 412a is formed from the front side of the semiconductor substrate 401 through the emitter region 422 and the first body region 424. The bottom end of the first trench part 412a in the depth direction protrudes into the first drift region 426 by a specified length. The gate electrode 16 inside the first trench part 412a is covered with the insulating layer 442 on the upper surface and insulated from the front-side electrode 440. However, the gate electrode 416 is allowed to make contact with the outside at the position that is not shown in drawings.

The diode region 480 is formed with an anode region 482, a cathode region 484, and a plurality of gate electrodes 416.

The anode region 482 is p-type and formed in an area that is exposed to the front side of the diode region 480. The impurity concentration of the anode region 482 is approximately the same as that of the first body region 424. The anode region 482 is formed such that the bottom end thereof in the depth direction is positioned deeper than the bottom end of the first body region 424. The front side of the anode region 482 is ohmically connected to the front-side electrode 440. It should be noted that the positional relation between the position of the bottom end of the anode region 482 according to this embodiment and the position of the bottom end of the first body region 424 is only an example, and various positional relations may be used in other examples.

The cathode region 484 is n-type and disposed at a deeper position than the anode region 482. The impurity concentration of the cathode region 484 is approximately the same as that of the first drift region 426. The cathode region 484 is formed contiguously with the first drift region 426. The cathode region 484 is formed in an area that is exposed to the back side of the semiconductor substrate 401. The back side of the cathode region 484 is ohmically connected to the back-side electrode 430.

The first trench part 412a is also formed within the diode region 480. In the diode region 480, the first trench part 412a is formed from the front side of the semiconductor substrate 401 through the anode region 482. The bottom end of the first trench part 412a faces the front side of the cathode region 484. As described above, the gate electrode 416 that is enclosed with the gate insulating film 414 is provided inside the first trench part 412a.

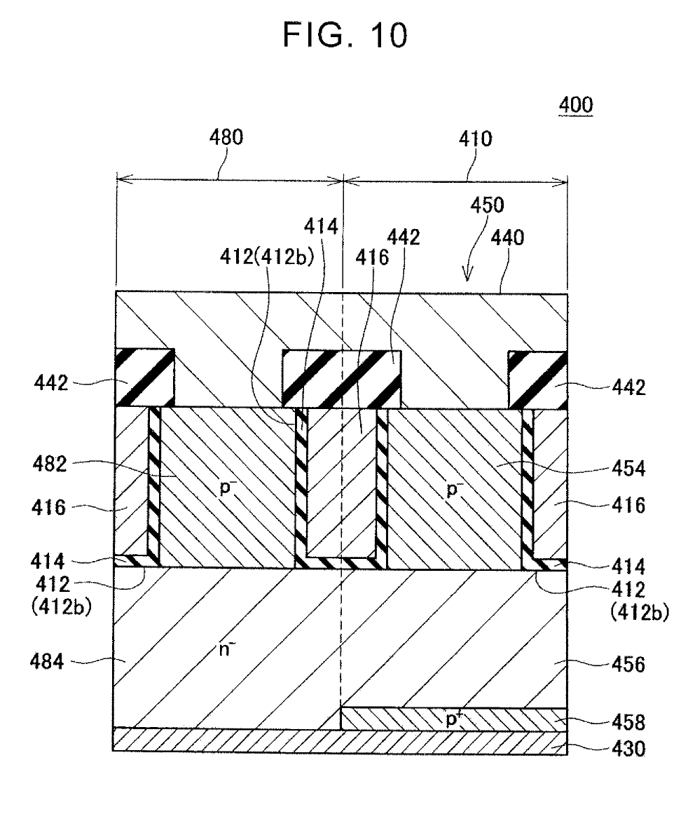

Next, the non-channel region 450 within the IGBT region 410 will be described with reference to FIG. 10.

As shown in FIG. 10, the non-channel region 450 is formed with a second body region 454, a second drift region 456, a second collector region 458, and a plurality of gate electrodes 416. These regions 454 through 458 and a gate electrode 416 described above are the same as the regions 54 through 58 and the gate electrode 16 in the non-channel region 450 of the semiconductor device (IGBT) 10 according to the first embodiment.

The diode region 480 shown in FIG. 10 has the same structure as the diode region 480 shown in FIG. 9. It should be noted that the impurity concentration of the anode region 482 is approximately the same as that of the second body region 454. The bottom end of the anode region 482 is formed in the same depth as the bottom end of the second body region 454. The impurity concentration of the cathode region 484 is approximately the same as that of the second drift region 456. The cathode region 484 is formed contiguously with the second drift region 456.

Operation of the semiconductor device 400 according to this embodiment will be described next. First, a case where the IGBT region 410 is operated is described. The voltage in which the back-side electrode 430 becomes positively charged (that is to say, the forward voltage to the IGBT region 410 (backward voltage to the diode region 480)) is applied between the front-side electrode 440 and the back-side electrode 430. The ON-potential is applied to the gate electrode 416. This causes the IGBT to be turned on. In other words, for the channel region 420 (see FIG. 9), a channel is formed within the first body region 424 in a range in contact with the gate insulating film 414 due to the application of the ON-potential to the gate electrode 416. Subsequently, an electron flows from the front-side electrode 440 to the back-side electrode 430 through the emitter region 422, the channel, the first and the second drift regions 426 and 456, and the first and the second collector regions 428 and 458. Additionally, a hole flows from the back-side electrode 430 to the front-side electrode 440 through the first and the second collector regions 428 and 458, the first and the second drift regions 426 and 456, and the first and the second body regions 424 and 454. In other words, an electric current flows from the back-side electrode 430 to the front-side electrode 440. On the other hand, for the non-channel region 450 that includes no emitter region 422 (see FIG. 10), a channel is not formed within the second body region 454 in a range in contact with the gate insulating film 414 when the ON-potential is applied to the gate electrode 416.

The channel that is formed within the channel region 420 vanishes when the potential applied to the gate electrode 416 is changed from the ON-potential to OFF-potential. However, a carrier that remains in the first drift region 426 and the second drift region 456 keeps the electric current (referred to as a tail current) flowing through the semiconductor device 400 for a short time. The tail current attenuates within a short time, and then the electric current flowing through the semiconductor device 400 becomes approximately zero. That is to say, the semiconductor device 400 is turned off While the semiconductor device 400 is turned off, a depletion layer is formed in the IGBT region 410 between the first body region 424 and the second body region 454 and between the first drift region 426 and the second drift region 456. While the semiconductor device 400 is turned off, a depletion layer is also formed in the diode region 480 between the anode region 482 and the cathode region 484.

Subsequently, a case where the diode region 480 is operated is described. The voltage in which the front-side electrode 440 becomes positively charged (that is to say, the forward voltage to the diode region 480 (backward voltage to the IGBT region 410)) is applied between the front-side electrode 440 and the back-side electrode 430. This causes a diode to be turned on. It should be noted that the ON-potential is not applied to the gate electrode 416 in this case. The electric current flows from the front-side electrode 440 to the back-side electrode 430 via the anode region 482 and the cathode region 484 when the diode is turned on. When the voltage applied to the diode is changed from the forward voltage to the backward voltage, the diode achieves a reverse recovery operation. In other words, the hole existing in the cathode region 484 at the application of the forward voltage is emitted to the front-side electrode 440, and the electron existing in the cathode region 484 at the application of the forward voltage is emitted to the back-side electrode 430. This causes the backward current to flow through the diode. The backward current attenuates within a short time, and then the electric current flowing through the diode becomes approximately zero.

The structure and operation of the semiconductor device 400 according to this embodiment has been described so far. The semiconductor device 400 according to this embodiment can provide the same operation and effects as the semiconductor device 10 according to the first embodiment described above.

While techniques disclosed herein have been described in detail with reference to example embodiments thereof, it is to be understood that those examples are merely illustrative and claims of the present invention are not limited to those examples. The techniques that are disclosed in the claims of the present invention are intended to cover various modifications and changes of the example embodiments that are described above. For example, the following modifications may be used.

### Modification 1

In the embodiments described above, the trench 12 (412) is formed in a uniform depth at any part. However, the present invention is not limited to this, and the trench 12 (412) may have different depth at different places. In that case, the first trench part 12a (412a) arranged in the channel region 20 (420) may be formed deeper than the second trench part 12b (412b). The bottom end of the first body region 24 (424) may be formed in the same depth as the bottom end of the second body region 54 (454). According to this modification, even when the bottom end of the first body region 24 (424) is formed in the same depth as the bottom end of the second body region 54 (454), the protruding length of the second trench part 12b (412b) that protrudes into the second drift region 56 (456) can be formed shorter than the protruding length of the first trench part 12a (412a) that protrudes into the first drift region 26 (426). Therefore, this modification can also provide the same operation and effects as the embodiments described above.

### Modification 2

The above first through fourth embodiments have been described for the cases where the semiconductor device is the IGBT. However, the semiconductor device is not limited to the IGBT and may be a MOSFET. Even if the semiconductor device is the MOSFET, the techniques described in the first through the fourth embodiments can be applied.

In addition, the technical elements that are described in this specification and the drawings demonstrate technical utility when used singly or in various combinations. The techniques that are illustrated in this specification and the drawings achieve a plurality of objects simultaneously, and the achievement of one object thereof itself has technical usefulness.

What is claimed is:

1. A semiconductor device comprising:
a channel region, including: a contact region of a first conductive type; a first body region of a second conductive type that is disposed at a deeper position than the contact region and adjacent to the contact region; a first drift region of the first conductive type that is disposed at a deeper position than the first body region and separated from the contact region with the first body region; and a first trench gate that penetrates through the contact region and the first body region, in which a bottom end in a depth direction protrudes into the first drift region, a first insulating film comes in contact with an inner surface of the first trench gate, and a first gate electrode comes in contact with the first insulating film, and
a non-channel region, including: a second body region of the second conductive type in which the contact region is disposed at the same depth position as an opposite surface of a surface adjacent to the first body region; a second drift region of the first conductive type that is disposed at a deeper position than the second body region and adjacent to the second body region; and a second trench gate that penetrates through the second body region, in which a bottom end in the depth direction protrudes into the second drift region, that is adjacent to the first trench gate, in which a second insulating film in contact with an inner surface of the second trench gate comes in contact with the first insulating film, a second gate electrode in contact with the second insulating film comes in contact with the first gate electrode, and protruding length of the second trench gate is shorter than the protruding length of the first trench gate that protrudes into the first drift region.

2. The semiconductor device according to claim 1,
wherein the bottom end of the second body region in the depth direction is positioned deeper than the bottom end of the first body region in the depth direction.

3. The semiconductor device according to claim 1, further comprising:
a carrier storage region of the first conductive type that is provided between the second body region and the second drift region and has higher impurity concentration than the second drift region.

4. The semiconductor device according to claim 1,
wherein a floating region of the first conductive type that has higher impurity concentration than the second drift region is provided in the second body region.

5. The semiconductor device according to claim 1,
wherein a middle portion in the bottom end of the second body region is positioned deeper than a portion coming in contact with the second trench gate.

6. The semiconductor device according to claim 1,
wherein the channel region is disposed at a deeper position than the first drift region and provided with a first collector region of the second conductive type that is adjacent to the first drift region, and
the non-channel region is disposed at a deeper position than the second drift region and provided with a second collector region of the second conductive type that is adjacent to the second drift region and adjacent to the first collector region, and further comprising
a diode region that includes: an anode region of the second conductive type that is disposed at the same depth position as an opposite surface of a surface adjacent to the first body region in the contact region; and a cathode region of the first conductive type that is disposed at a deeper position than the anode region and adjacent to the anode region, and that is adjacent to the channel region and the non-channel region.

7. A semiconductor device comprising:
a semiconductor substrate that is provided with a trench, an insulating film which encloses an inner surfaces of the trench, and a gate electrode which is housed in the trench in an enclosed state by the insulating film;
wherein a channel region and a non-channel region are disposed along a longitudinal direction of the trench when the semiconductor substrate is viewed in a plan view; the trench includes a first trench part that is positioned within the channel region and a second trench part that is positioned within the non-channel region; a front-side electrode is connected on a front side of the semiconductor substrate; a back-side electrode is connected on a back side of the semiconductor substrate; when the semiconductor substrate is viewed from a first section that is cut along a plane orthogonal to the longitudinal direction of the trench in the channel region, the channel region includes: a contact region of a first conductive type that is provided on a front side of the semiconductor substrate; a first body region of a second conductive type that is disposed at a deeper position than the contact region and adjacent to the contact region; and a first drift region of the first conductive type that is disposed at a deeper position than the first body region and separated from the contact region with the first body region; the first trench part is formed from the front side of the semiconductor substrate through the contact region and the first body region, in which a bottom end in a depth direction protrudes into the first drift region; when the semiconductor substrate is viewed from a second section that is cut along a plane orthogonal to the longitudinal direction of the trench in the non-channel region, the non-channel region includes: a second body region of a second conductive type that is provided on a front side of the semiconductor substrate; and a second drift region of the first conductive type that is disposed at a deeper position than the second body region and adjacent to the second body region; the second trench part is formed from the front side of the semiconductor substrate through the second body region, in which a bottom end in a depth direction protrudes into the second drift region; and a protruding length of the second trench part protruding into the second drift region is shorter than that of the first trench part protruding into the first drift region.

8. The semiconductor device according to claim 7,
wherein the bottom end of the second body region in the depth direction is positioned deeper than the bottom end of the first body region in the depth direction.

9. The semiconductor device according to claim 7, further comprising:
a carrier storage region of the first conductive type that is provided between the second body region and the second drift region and has higher impurity concentration than the second drift region.

10. The semiconductor device according to claim 7,
wherein a floating region of the first conductive type that has higher impurity concentration than the second drift region is provided in the second body region.

11. The semiconductor device according to claim 7,
wherein a middle portion in the bottom end of the second body region is positioned deeper than a portion coming in contact with the second trench part.

12. The semiconductor device according to claim 7,
wherein the channel region is disposed at a deeper position than the first drift region and provided with a first collector region of the second conductive type that is adjacent to the first drift region, and
the non-channel region is disposed at a deeper position than the second drift region and provided with a second collector region of the second conductive type that is adjacent to the second drift region and adjacent to the first collector region, and further comprising
a diode region that includes: an anode region of the second conductive type that is disposed at the same depth position as an opposite surface of a surface adjacent to the first body region in the contact region; and a cathode region of the first conductive type that is disposed at a deeper position than the anode region and adjacent to the anode region, and that is adjacent to the channel region and the non-channel region.
